(19) United States
(12) Patent Application Publication
(10) Pub. No.: US 2017/0352636 A1
(43) Pub. Date: Dec. 7, 2017

(54) ANISOTROPIC CONDUCTIVE FILM AND CONNECTION STRUCTURE

(71) Applicant: DEXERIALS CORPORATION, Tokyo (JP)

(72) Inventor: Yasushi AKUTSU, Utsunomiya-shi (JP)

(73) Assignee: DEXERIALS CORPORATION, Tokyo (JP)

(21) Appl. No.: 15/521,189

(22) PCT Filed: Oct. 27, 2015
(86) PCT No.: PCT/JP2015/080233

§ 371 Date: Apr. 21, 2017

(30) Foreign Application Priority Data
Oct. 28, 2014 (JP) 2014-219794

(51) Int. Cl. H01L 23/00; H05K 1/14; G06F 17/50; B32B 37/12; H05K 1/11; H05K 1/02; H01L 23/498; H01B 1/22

(52) U.S. Cl. CPC H01L 24/29; H01L 24/32; G06F 17/5045; H05K 1/144; B32B 37/12; H05K 1/028; H01L 2924/14; H01L 2224/32225; H01L 2224/29499; H01L 2224/29387; H01L 2224/293; H01L 2224/2929; H01L 23/4985; H01B 1/22; B32B 2307/202; H05K 1/111; H05K 2201/0209; H05K 2201/0215; H05K 2201/041; H05K 2201/0266

(57) ABSTRACT

A anisotropic conductive film includes: an electrically insulating adhesive layer; electrically conductive particles disposed in lattice form in the electrically insulating adhesive layer; a reference electrically conductive particle defined, an electrically conductive particle closest to the reference electrically conductive particle defined as a first electrically conductive particle, an electrically conductive particle equally close or next closest to the reference electrically conductive particle regarding the first electrically conductive particle defined as a second electrically conductive particle. The second electrically conductive particle absent from lattice form axis including the reference electrically conductive particle and first electrically conductive particle. A projection image in the anisotropic conductive film longitudinal direction of the reference electrically conductive particle and first electrically conductive particle or second electrically conductive particle overlap and the anisotropic conductive film projection image in a short-side direction the reference electrically conductive particle and second electrically conductive particle or first electrically conductive particle overlap.

### TECHNICAL FIELD

The present invention relates to an anisotropic conductive film, a connection method using the anisotropic conductive film, and a connection structure connected via the anisotropic conductive film.

### BACKGROUND ART

Anisotropic conductive films are widely used when electronic components such as IC chips are mounted on boards. In recent years, demand has arisen for high density wiring/interconnections in small electronic devices such as mobile phones, and notebook computers. A technique is known for utilizing an anisotropic conductive film in such high density wiring/interconnections, in which electrically conductive particles are evenly disposed in a lattice form in an electrically insulating adhesive layer of the anisotropic conductive film.

However, there is a problem in that variations in connection resistance occur even though the electrically conductive particles are evenly disposed. This is because electrically conductive particles positioned on an edge of a terminal flow out into a space due to an insulating binder melting and are difficult to interpose between upper and lower terminals. To solve this problem, a technique has been proposed in which a first row direction of electrically conductive particles is configured as the longitudinal direction of an anisotropic conductive film, and a second row direction crossing the first row direction is configured to be inclined at not less than 5° and not greater than 15° with respect to a direction orthogonal to the longitudinal direction of the anisotropic conductive film (Patent Literature 1).

### CITATION LIST

### Patent Literature

Patent Literature 1: Japanese Patent No. 4887700B

### SUMMARY OF INVENTION

### Technical Problem

However, when a bump size of an electronic component to be connected by the anisotropic conductive film decreases, a number of electrically conductive particles that can be captured by the bump also decreases, and there is a situation where conduction reliability is not sufficiently obtained by the anisotropic conductive film described in Patent Literature 1. In particular, in a so-called COG (chip-on-glass) connection that connects a control IC of an LCD panel or the like to a transparent electrode on a glass substrate, the bump size decreases due to an increased terminal count, which accompanies a higher definition of the LCD panel, and size reduction of the IC chip, and even in a situation of making a FOG (film-on-glass) connection that joins a glass substrate for a television display and an FPC (flexible printed circuit), the connection terminals become fine-pitched, making increasing a number of electrically conductive particles that can be captured by the connection terminals and increasing the conduction reliability problematic.

Therefore, the present invention has as an object to enable stable conduction reliability to be obtained using an anisotropic conductive film not only in a conventional FOG connection or COG connection but also a FOG connection or COG connection of a fine pitch.

### Solution to Problem

The present inventor arrived at the present invention by finding that, in an anisotropic conductive film that disposes electrically conductive particles in a lattice form, in order to dispose the electrically conductive particles at a high density and prevent short-circuiting from occurring when an anisotropic conductive connection is conducted, with any electrically conductive particle made to serve as a reference (“reference electrically conductive particle” hereinbelow) and a first electrically conductive particle closest to the reference electrically conductive particle or a second electrically conductive particle next closest thereto, projection images in a longitudinal direction and a short-side direction of the anisotropic conductive film of the reference electrically conductive particle and the first electrically conductive particle or the second electrically conductive particle are made to overlap and overlap-widths thereof are made to be in specified ranges, thereby improving connective reliability of the anisotropic conductive film.

That is, the present invention is an anisotropic conductive film, including: an electrically insulating adhesive layer; and electrically conductive particles disposed in a lattice form in the electrically insulating adhesive layer; wherein

a reference electrically conductive particle is defined,

an electrically conductive particle closest to the reference electrically conductive particle is defined as a first electrically conductive particle, and

an electrically conductive particle equally close or next closest to the reference electrically conductive particle with regard to the first electrically conductive particle is defined as a second electrically conductive particle, the second electrically conductive particle being absent from a lattice form axis including the reference electrically conductive particle and the first electrically conductive particle,

a projection image in a longitudinal direction of the anisotropic conductive film of the reference electrically conductive particle and the first electrically conductive particle or the second electrically conductive particle overlap,

a projection image in a short-side direction of the anisotropic conductive film of the reference electrically conductive particle and the second electrically conductive particle or the first electrically conductive particle overlap, and

at least a maximum width in the short-side direction of the anisotropic conductive film of an overlap region between the projection image in the longitudinal direction of the anisotropic conductive film of the reference electrically conductive particle and the first electrically conductive particle or the second electrically conductive particle (“overlap width between electrically conductive particles adjacent in the longitudinal direction of the anisotropic conductive film” hereinbelow) or a maximum width in the longitudinal direction of the anisotropic conductive film of an overlap region between the projection image in the short-side direction of the anisotropic conductive film of the reference electrically conductive particle and the second electrically conductive particle or the first electrically conductive particle (“overlap width between electrically conductive particles adjacent in the short-side direction of the anisotropic conductive film” hereinbelow) is less than 1 time a particle diameter of the electrically conductive particle.

Furthermore, the present invention provides a connection structure, including a first electronic component and a second electronic component, wherein the first electronic component and the second electronic component are anisotropically conductively connected via the anisotropic conductive film described above.

### Advantageous Effects of Invention

According to the anisotropic conductive film of the present invention, by disposing the electrically conductive particles in the electrically insulating adhesive layer at a high density, the electrically conductive particles can be reliably captured by terminals between which an anisotropic conductive connection is made even if an area of these terminals is small and short-circuiting arising due to the electrically conductive particles can be suppressed even if the terminals are formed at a fine pitch.

### BRIEF DESCRIPTION OF DRAWINGS

FIG. 1 is a disposition diagram of electrically conductive particles in an anisotropic conductive film 1A of the Examples.

FIG. 2 is a disposition diagram of electrically conductive particles in an anisotropic conductive film 1B of the Examples.

FIG. 3 is a disposition diagram of electrically conductive particles in an anisotropic conductive film 1C of the Examples.

FIG. 4 is a disposition diagram of electrically conductive particles in an anisotropic conductive film 1D of the Examples.

FIG. 5 is a disposition diagram of electrically conductive particles in an anisotropic conductive film 1x of the Comparative examples.

FIG. 6 is a disposition diagram of electrically conductive particles in an anisotropic conductive film 1y of the Comparative examples.

### DESCRIPTION OF EMBODIMENTS

Next, the present invention will be described in detail while referring to the drawings. Note that in the drawings, identical reference signs indicate the same constituents.

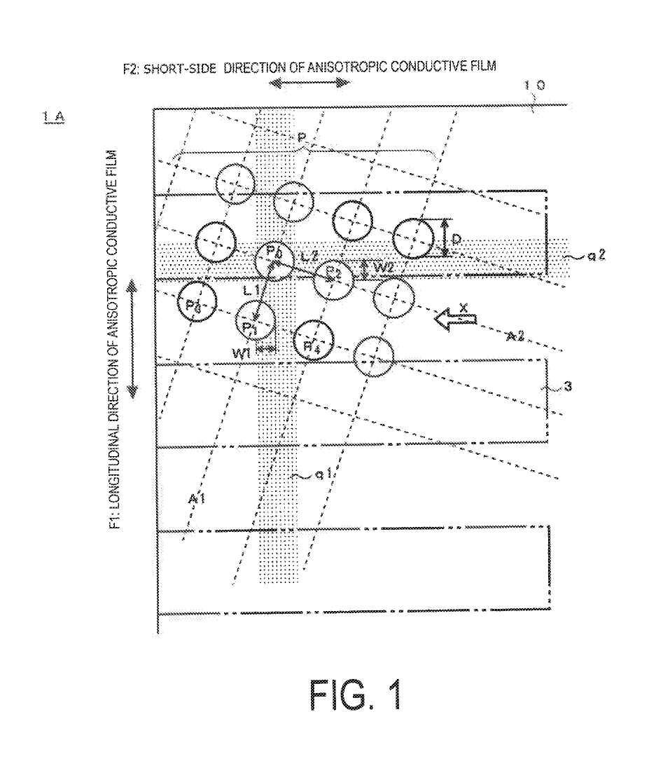

FIG. 1 is a disposition diagram of electrically conductive particles P in an anisotropic conductive film 1A of an embodiment of the present invention. This anisotropic conductive film 1A has an electrically insulating adhesive layer 10 and electrically conductive particles P fixed in a lattice form disposition in the electrically insulating adhesive layer 10.

More specifically, the electrically conductive particles P are disposed in a square lattice form or a rectangular lattice form in the electrically insulating adhesive layer 10; a lattice form axis including a reference electrically conductive particle P0 and a first electrically conductive particle P1 closest to this reference electrically conductive particle P0 (“first row axis A1” hereinbelow) is inclined relative to a longitudinal direction F1 and a short-side direction F2 of the anisotropic conductive film 1A. Here, a center distance between the reference electrically conductive particle P0 and the first electrically conductive particle P1 is L1.

Furthermore, a lattice form axis including a second electrically conductive particle P2, which is an electrically conductive particle equally close or next closest to the reference electrically conductive particle P0 with regard to the first electrically conductive particle P1 and is absent from first row axis A1, and the reference electrically conductive particle P0 (“second row axis A1” hereinbelow) is also inclined relative to the longitudinal direction F1 and the short-side direction F2 of the anisotropic conductive film 1A. Here, defining a center distance between the reference electrically conductive particle P0 and the second electrically conductive particle P2 to be L2, L2≧L1.

The center distance L1 between the reference electrically conductive particle P0 and the first electrically conductive particle P1 and the center distance L2 between the reference electrically conductive particle P0 and the second electrically conductive particle P2 can be suitably determined according to an FOG connection or a COG connection or the like for which the anisotropic conductive film is applied, and are normally from 1.5 to 2000 times a particle diameter D of the electrically conductive particle P. In the FOG connection, they are preferably 2.5 to 1000 times thereof, more preferably 3 to 700 times thereof, and particularly preferably greater than 5 times and less than 400 times thereof. In the COG connection, they are preferably 1.5 to 5 times thereof, more preferably 1.8 to 4.5 times thereof, and particularly preferably 2 to 4 times thereof. By the electrically conductive particles P being disposed at a high density in this manner, even if an area of a terminal that makes an anisotropic conductive connection using the anisotropic conductive film 1A is small, the electrically conductive particles P are reliably captured by this terminal and conduction reliability can be obtained. In contrast, when the center distances L1, L2 are too short, short-circuiting is more likely to arise in a situation where terminals are connected using the anisotropic conductive film; conversely, when these are too long, a number of electrically conductive particles captured between the terminals becomes insufficient.

In this anisotropic conductive film 1A, a projection image q1 in the longitudinal direction of the anisotropic conductive film of the reference electrically conductive particle P0 (that is, an image in a situation where the reference electrically conductive particle P0 is projected by a parallel light in the longitudinal direction F1 of the anisotropic conductive film 1A) and the first electrically conductive particle P1 overlap and a projection image q2 in the short-side direction F2 of the anisotropic conductive film of the reference electrically conductive particle P0 (that is, an image in a situation where the reference electrically conductive particle P0 is projected by a parallel light in the short-side direction F2 of the anisotropic conductive film 1A) and the second electrically conductive particle P2 overlap. Moreover, an overlap width W1 between the reference electrically conductive particle P0 and the first electrically conductive particle P1, which are adjacent in the longitudinal direction E1 of the anisotropic conductive film 1A, and an overlap width W2 between the reference electrically conductive particle P0 and the second electrically conductive particle P2, which are adjacent in the short-side direction F2 of the anisotropic conductive film 1A, are greater than 0 times and less than 1 time, preferably less than 0.5 times, the particle diameter D of the electrically conductive particle P.

Note that in the present invention, the particle diameter D of the electrically conductive particle P is an average particle diameter of the electrically conductive particle used in the anisotropic conductive film. From the perspective of preventing short-circuiting and the stability of the connection of the opposing terminals, the particle diameter D of the electrically conductive particles P is preferably from 1 to 30 μm, and more preferably from 2 to 15 μm. Note that the particle diameter D of the electrically conductive particle and a range of a particle center distance of the electrically conductive particles D are closely related; for example, in a situation of general FPC wiring, supposing that the length of the connection area is typically 2 mm, and two electrically conductive particles of a particle diameter of 1 μm are captured on one row axis with a margin of 0.5 times the electrically conductive particle diameter, an upper limit of the particle center distance can be calculated as 1998 times the particle diameter (in this situation, a distance from a row axis adjacent to this row axis becomes sufficiently short). From a reason similar to the above, in situations of FOG connections with electrically conductive particles of particle diameters of 2 μm and 3 μm, the upper limit of the particle center distance can be calculated as 998 times the particle diameter and 663.7 μm (this is also a range that can include a situation where three electrically conductive particles of 1 μm are present in 2 mm). Moreover, in a situation where a width of the general FPC wiring is made to be 200 μm and L/S=1, supposing that in 400 μm, which is a total of the wiring width and a space thereof, two electrically conductive particles of a minimum diameter of 1 μm can be present on one row axis with a margin of 0.5 times the electrically conductive particle and on an inner side of an end portion of the wiring, the upper limit of the particle center distance can be calculated as less than 398 times the particle diameter. Moreover, in a situation where the particle diameter D of the electrically conductive particle is 30 μm, a lower limit of the particle center distance corresponds to an interval at which disposition is possible with a margin.

As described above, in this anisotropic conductive film 1A, both the overlap width W1 between the reference electrically conductive particle P0 and the first electrically conductive particle P1 adjacent in the longitudinal direction F1 and the overlap width W2 between the reference electrically conductive particle P0 and the second electrically conductive particle P2 adjacent in the short-side direction F2 of the anisotropic conductive film 1A are less than 1 time the particle diameter D of the electrically conductive particle P, but in the present invention, it is sufficient for at least one among these overlap widths W1, W2 to be less than 1 time the particle diameter D of the electrically conductive particle P. In other words, there is no situation where both overlap widths W1, W2 simultaneously become equal to the particle diameter D of the electrically conductive particle P. That is, there is no situation where the projection image q1 of the reference electrically conductive particle P0 and the first electrically conductive particle P1 or the second electrically conductive particle P2 overlap exactly and there is no situation where the projection image q2 of the reference electrically conductive particle P0 and the second electrically conductive particle P2 or the first electrically conductive particle P1 overlap exactly.

By adjusting the overlap widths W1, W2 in this manner, regardless of the electrically conductive particles P being disposed at a high density, short-circuiting arising between the terminals in a situation where an anisotropic conductive connection is made between the terminals using the anisotropic conductive film 1A can be suppressed. Moreover, by intentionally shifting even in a state of high-density disposition, even if a failure were to arise when manufacturing the an isotropic conductive film, this would be able to be easily detected. For example, by drawing a straight line (extension line) in the longitudinal or short-side direction of the film or at an angle of a predetermined skew relative to these directions on a surface field image at any location, it can be easily confirmed whether a row axis is formed matching an initial design.

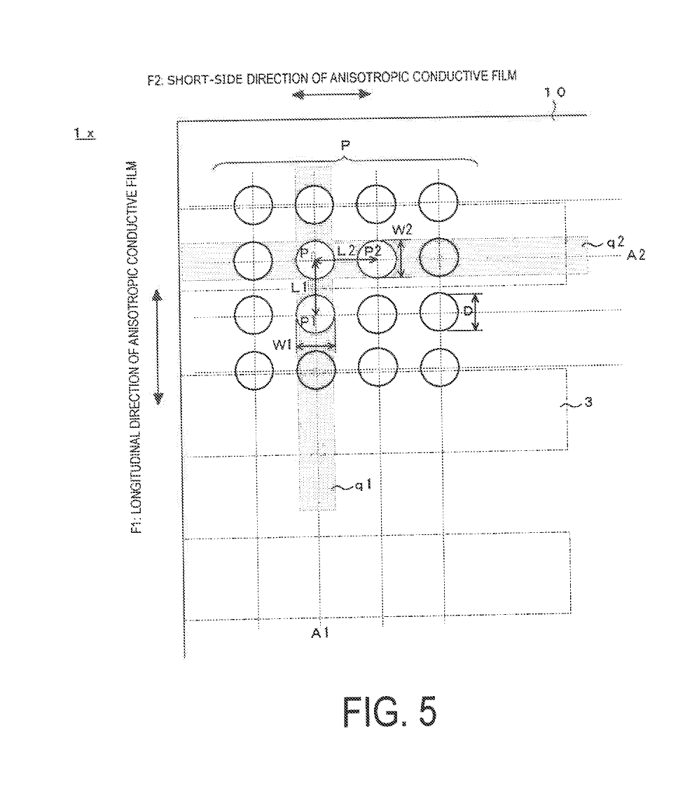

This effect of short-circuiting suppression is thought to be obtained by a mechanism of action such as follows between the electrically conductive particles P and the electrically insulating adhesive layer 10. That is, in a situation of making an anisotropic conductive connection to a connection terminal 3 of an electronic component using the anisotropic conductive film 1A, for example, as illustrated in FIG. 1, when the longitudinal direction F1 of the anisotropic conductive film 1A and a short-side direction of the connection terminal 3 are matched and heating and pressurizing are performed by a heating head covering the connection terminal 3, the electrically insulating adhesive layer 10 melts, a melted resin thereof flows in an arrow-X direction, and the electrically conductive particles P between the connection terminals 3 also moves in the arrow-X direction due to the flow of the melted resin. Here, when both the overlap widths W1 and W2 are equal to the particle diameter D of the electrically conductive particle P gas in an anisotropic conductive film 1x of a comparative example illustrated in FIG. 5, at the time of the anisotropic conductive connection, the electrically conductive particles P between the connection terminals 3 line up in a row in the arrow-X direction as well as a direction orthogonal thereto, facilitating connection of a plurality of three or more—electrically conductive particles P due to the flow of the melted resin. Because of this, in a situation of connecting a connection terminal of a fine pitch, short-circuiting becomes more likely to arise.

In contrast, in this anisotropic conductive film 1A, as illustrated in FIG. 1, positions in the longitudinal direction F1 of the anisotropic conductive film 1A of electrically conductive particles P3, P1, P4 adjacent in an X direction are shifted; therefore, flow of the melted resin is disturbed, three or more electrically conductive particles connecting after flowing in the melted resin is prevented, and a connection can be made without causing short-circuiting even for a connection terminal of a fine pitch. That is, it becomes possible to impart a margin to a design of a molten viscosity of the film. For example, when the electrically conductive particles are present at a high density and the molten viscosity is designed to be comparatively high to suppress flow of the electrically conductive particles, a concern arises of inhibiting pushing. However, by designing as above, such a problem becomes easy to avoid. Moreover, because a behavior of a flowing state is easy to grasp even at a stage of formulation design, this can also contribute to reduction of design effort.

In this connection of a fine pitch, in a parallel direction of the connection terminal including opposing connection terminals connecting to each other, a minimum inter-terminal distance by which the terminals are adjacent to each other at an interval (this distance may be shifted in the parallel direction in a range where anisotropic conductive connection is possible) can be made to be less than 4 times the particle diameter D of the electrically conductive particle. In this situation, a width in a short-side direction of a connection surface of the connected terminal can be made to be less than 7 times the particle diameter D of the electrically conductive particle.

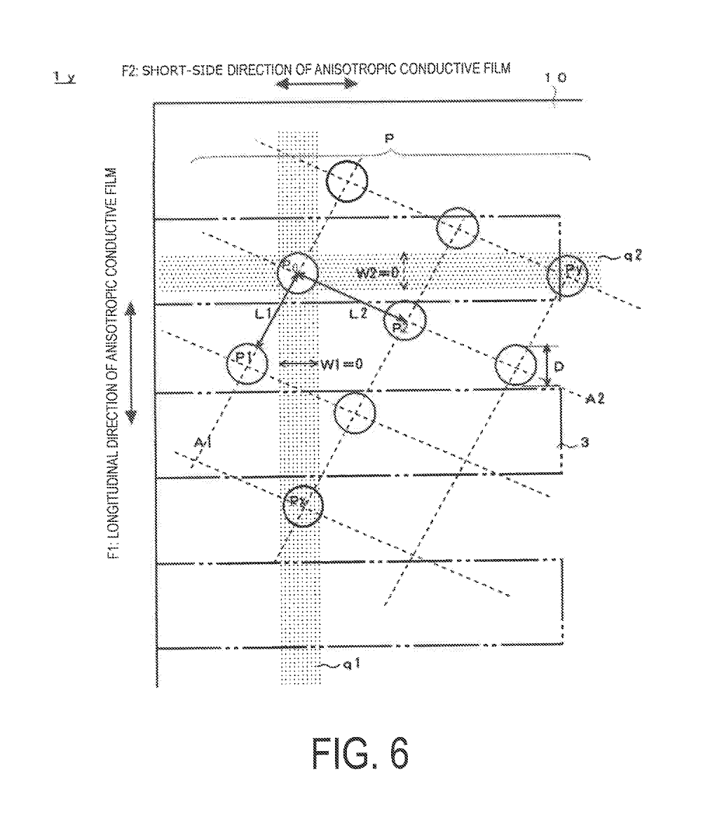

Furthermore, as in an anisotropic conductive film 1y of a comparative example illustrated in FIG. 6, in a situation where the first electrically conductive particle P1 closest to the reference electrically conductive particle P0 overlaps neither the projection image q1 in the longitudinal direction F1 of the anisotropic conductive film of the reference electrically conductive particle P0 nor the projection image q2 in the short-side direction F2 and electrically conductive particles Px, Py further away from the reference electrically conductive particle P0 than the first electrically conductive particle P1 overlap the projection images q1, q2 of the reference electrically conductive particle P0, short-circuiting becomes less likely to arise because the density of the electrically conductive particles P decreases. However, because the density of the electrically conductive particles P is low, in a situation where a size of a terminal to be connected is small, the electrically conductive particles P are less likely to be captured by the terminal 3, reducing conduction reliability. Generally, as illustrated in FIG. 6, in an IC chip or the like, a plurality of connection terminals 3 is in parallel and the anisotropic conductive film is affixed to the connection terminals along a row direction of the connection terminals 3; however, when shifting or deflection arises in this affixing, electrically conductive particles P disposed sparsely on the connection terminals 3 become further less likely to be captured by the connection terminals.

In contrast, the anisotropic conductive film 1A of the present invention can improve the conduction reliability.

The anisotropic conductive film of the present invention can take various forms. For example, in the anisotropic conductive film 1A described above, the projection image q1 in the longitudinal direction F1 of the anisotropic conductive film 1A of the reference electrically conductive particle P0 and the second conductive particle may overlap and the projection image q2 in the short-side direction F2 of the anisotropic electrically conductive film 1A of the reference electrically conductive particle P0 and the first electrically conductive particle may overlap.

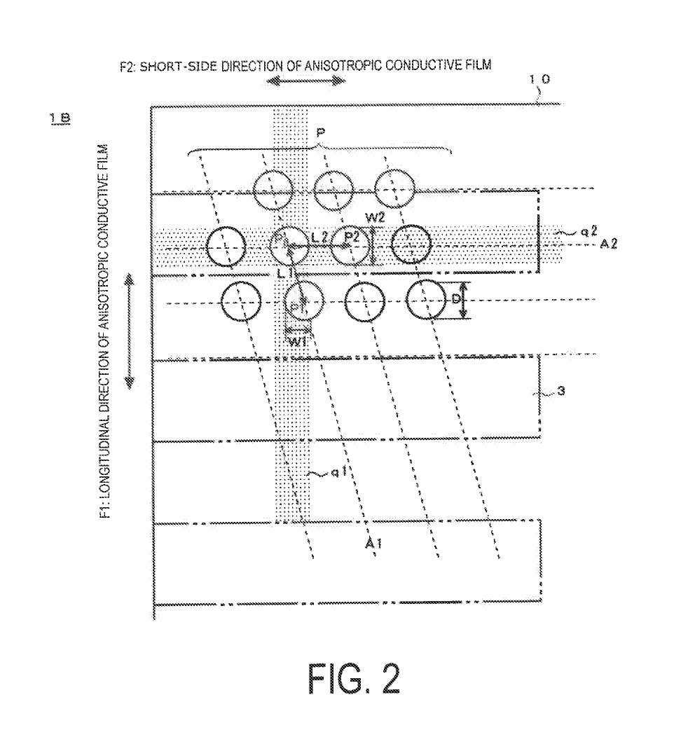

Furthermore, as in an anisotropic conductive film 1B illustrated in FIG. 2, the disposition of the electrically conductive particles P in the anisotropic conductive film described above may be made to be an oblique lattice form and the overlap width W2 between the reference electrically conductive particle P0 and the second electrically conductive particle P2 adjacent in the short-side direction F2 of the anisotropic conductive film may be made equal to the particle diameter D of the electrically conductive particle P. In this situation, the overlap width W1 between the reference electrically conductive particle P0 and the first electrically conductive particle P1 adjacent in the longitudinal direction F1 of the anisotropic conductive film 1B is made to be less than 1 time, preferably less than 0.5 times, the particle diameter D of the conductive particle P. In this aspect, it is preferable for an outer tangent line in the longitudinal direction F1 of the anisotropic conductive film of the reference electrically conductive particle P0 to not overlap that of the first electrically conductive particle P1. That is, it is preferable for the outer tangent line in the longitudinal direction F1 of the anisotropic conductive film of the reference electrically conductive particle P0 to pass through the first electrically conductive particle P1.

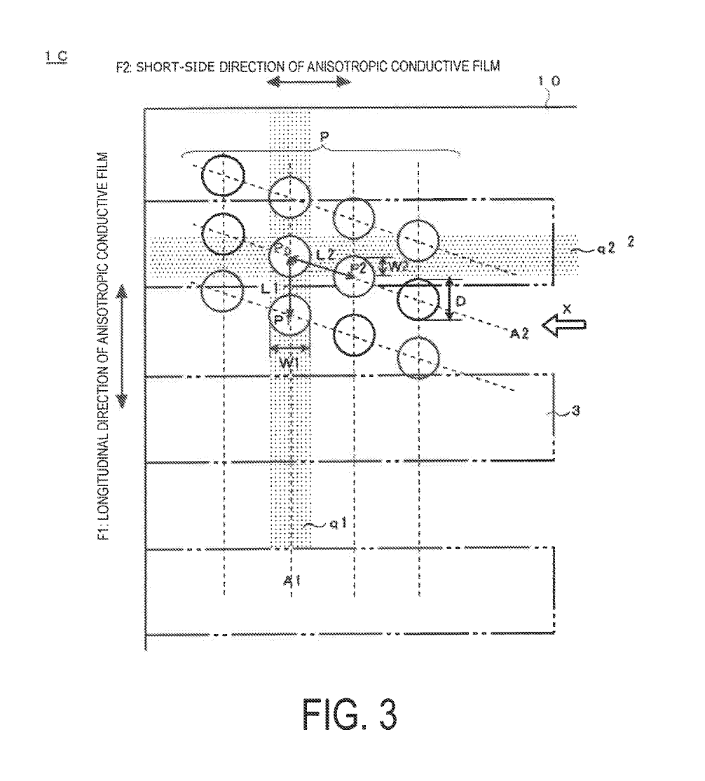

As in an anisotropic conductive film 1C illustrated in FIG. 3, in the anisotropic conductive film 1A described above, the disposition of the electrically conductive particles P may be an oblique lattice form and the overlap width W1 between the reference electrically conductive particle P0 and the first electrically conductive particle P1 adjacent in the longitudinal direction F1 of the anisotropic conductive film may be made equal to the particle diameter D of the electrically conductive particle P. In this situation, the overlap width W2 between the reference electrically conductive particle P0 and the second electrically conductive particle P2 adjacent in the short-side direction F2 of the anisotropic conductive film 1C is made to be less than 1 time, preferably less than 0.5 times, the particle diameter D of the electrically conductive particle P. In this aspect, it is preferable for an outer tangent line in the short-side direction F2 of the anisotropic conductive film of the reference electrically conductive particle P0 to not overlap that of the second electrically conductive particle P2. That is, it is preferable for the outer tangent line in the short-side direction F2 of the anisotropic conductive film of the reference electrically conductive particle P0 to pass through the second electrically conductive particle P2.

When, as in this anisotropic conductive film 1C, the electrically conductive particles P are arranged in a row in the longitudinal direction F1 of the anisotropic conductive film and the conductive particles P adjacent in the short-side direction F2 of the anisotropic conductive film are made to shift in the overlap width W2 less than 1 time the particle diameter D of the electrically conductive particle P, the electrically conductive particles P are disposed inclined only in the X direction, which is the flow direction of the resin; therefore, the electrically conductive particles captured by the connection terminal 3 and the electrically conductive particles moved by the resin flow can be easily grasped. Moreover, because superposition of the electrically conductive particles P in the flow direction decreases, short-circuiting can be suppressed in particular.

Note that by designing the disposition of the electrically conductive particles P in this manner in consideration of the flow of the resin at the time of connection, a freedom of a formulation of an insulating binder forming the electrically insulating adhesive layer 10 can be increased and preparation for a change in manufacture conditions or connection conditions of the anisotropic conductive film is facilitated.

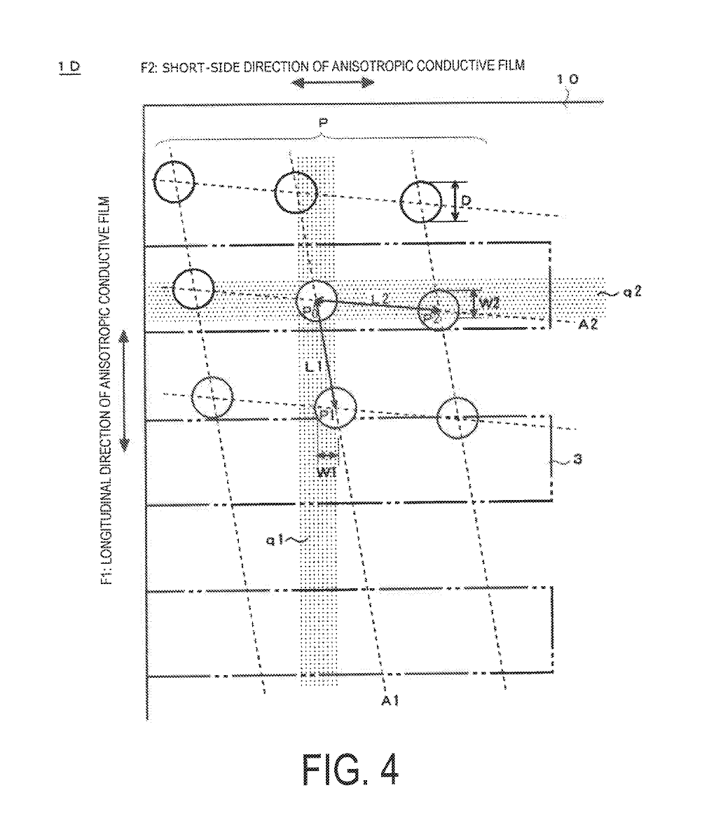

As in an anisotropic conductive film 1D illustrated in FIG. 4, the disposition of the electrically conductive particles P in the anisotropic conductive film 1A may be made an oblique lattice form.

In the present invention, the density of the electrically conductive particles P is preferably from 400 to 250000 particles/mm², more preferably from 800 to 200000 particles/mm², and further preferably from 1200 to 100000 particles/mm². This particle density is appropriately adjusted depending on the particle diameter D and the position in which the electrically conductive particles P are disposed.

In the anisotropic conductive film 1A, the constituent material of the electrically conductive particles P themselves and the layer structure or constituent resin of the electrically insulating adhesive layer 10 can take various forms.

That is, any material used in conventional anisotropic conductive films may be appropriately selected and used as the electrically conductive particles P. Examples thereof include nickel, cobalt, silver, copper, gold, palladium, and similar metal particles, metal-coated resin particles, and the like. A combination of two or more materials may also be used.

Any electrically insulating resin layer used in conventional anisotropic conductive films may be appropriately used as the electrically insulating adhesive layer 10. Examples thereof include a photo-radical polymerization type resin layer containing an acrylate compound and a photo-radical polymerization initiator, a thermal radical polymerization type resin layer containing an acrylate compound and a thermal radical polymerization initiator, a thermal cationic polymerization type resin layer containing an epoxy compound and a thermal cationic polymerization initiator, a thermal anionic polymerization type resin layer containing an epoxy compound and a thermal anionic polymerization initiator, and the like. Additionally, as necessary, polymerized products of these resin layers may be used to fix the electrically conductive particles P in the electrically insulating adhesive layer 10. Moreover, the electrically insulating adhesive layer 10 may be formed from a plurality of resin layers.

Furthermore, to fix the electrically conductive particles P in the electrically insulating adhesive layer 10, an insulating filler such as silica may be formulated in the electrically insulating adhesive layer 10 as necessary.

An example of a method for fixing the electrically conductive particles P in the electrically insulating adhesive layer 10 at the disposition described above includes fabricating a mold having recesses corresponding to the disposition of the electrically conductive particles P by machining, laser processing, photolithography, or the like; placing the electrically conductive particles into the mold; filling the mold with an electrically insulating adhesive layer forming composition; curing; and removing the product from the mold. A mold made from a material with lower rigidity may be fabricated from this mold.

Additionally, a method including providing a member, which includes through-holes defined in a predetermined disposition, on the electrically insulating adhesive layer forming composition; supplying the electrically conductive particles P from there above; and causing the electrically conductive particles P to pass through the through-holes may be used to place the electrically conductive particles P in the electrically insulating adhesive layer 10 at the disposition described above.

In a situation of using the anisotropic conductive film of the present invention to make an anisotropic conductive connection between a connection terminal of a first electronic component such as a flexible board (FPC), a glass substrate, a plastic substrate (a substrate consisting of a thermoplastic resin such as PET), or a ceramic substrate and a connection terminal of a second electronic component such as an IC chip, an IC module, or a flexible board (FPC), for example, as illustrated in FIG. 1, the longitudinal direction F1 of the anisotropic conductive film 1A and the short-side direction of the connection terminal 3 of the first electronic component or the second electronic component are matched. By this, the disposition of the electrically conductive particles P in the anisotropic conductive film 1A of the present invention can be utilized to sufficiently increase a capture count of the electrically conductive particles P in the connection terminal 3; in particular, in a situation where at least one among the first row axis A1 and the second row axis A2 of the electrically conductive particles P is inclined relative to the longitudinal direction F1 or the short-side direction F2 of the anisotropic conductive film, a capturability of the electrically conductive particles P in the connection terminal 3 can be remarkably increased.

More specifically, for example, in a situation of using, as the first electronic component, a glass substrate or the like where a connection terminal is formed by a transparent electrode and using, as the second electronic component, an IC chip or the like to make a COG connection of high-density wiring—more specifically, in a situation where a size of a connection surface of these connection terminals is 8 to 60 μm wide and no greater than 400 μm long (a lower limit being equal to the width)—the number of electrically conductive particles that can be captured by the connection terminal stably increases compared to a conventional anisotropic conductive connection and the connective reliability can be improved. Note that when the width in the short-side direction of the connection terminal surface is smaller than this, connection failure occurs frequently, but when this width is greater than this, high-density mounting, which is necessary in a COG connection, becomes difficult. Moreover, when the length of the connection terminal surface is shorter than this, stable conduction becomes difficult, but when this length is longer than this, this becomes a cause of uneven contact. Moreover, in a situation where short-circuiting is comparatively less likely to arise with a wiring distance of 40 μm or greater, as in using the flexible board (FPC) as the second electronic component, an electrically conductive particle of a comparatively large diameter of 6 μm or greater can be used (an upper limit of the particle diameter depends on the space but is preferably 30 μm or less, more preferably 15 μm or less, and further preferably less than 15 μm). By using such a comparatively large electrically conductive particle, a stable connection can be made even if there is minor variation in a position of a wiring height in the connection surface of the first electronic component. A ceramic substrate whose surface is warped due to a manufacture problem can be mentioned as an example where such a variation arises in the position of the wiring height.

The present invention also includes connection structures where anisotropic conductive connection is made between the first electronic component and the second electronic component in this manner.

### EXAMPLES

Next, the present invention will be described in detail on the basis of examples.

### Examples 1 to 3, Comparative Example 1

### (1) Manufacture of Anisotropic Conductive Film

A mixed solution of an insulating resin including 60 parts by mass of a phenoxy resin (thermoplastic resin) (YP-50, Nippon Steel & Sumikin Chemical Co., Ltd.), 40 parts by mass of an epoxy resin (thermosetting resin) (jER 828, Mitsubishi Chemical Corporation), 2 parts by mass of a cationic curing agent (SI-60L, Sanshin Chemical Industry Co., Ltd.), and 20 parts by mass of a silica microparticle (AEROSIL RY 200, Nippon Aerosil Co., Ltd.) is formulated, and this is coated on a PET film with a film thickness of 50 μm and dried for 5 minutes in an 80° C. oven to form an adhesive layer with a thickness of 20 μm on the PET film.

On the other hand, molds having convex row patterns at the arrangements illustrated in Table 1 were fabricated, conventionally known transparent resin pellets were melted and, while melted, poured into the molds, and the melted transparent resin was cooled and allowed to harden. Thus, resin molds having concaves in the row patterns illustrated in Table 1 were formed. The concaves of the resin molds were filled with the electrically conductive particles (AUL704, Sekisui Chemical Co., Ltd., particle diameter: 4 nm), and the adhesive layer, namely the electrically insulating adhesive layer described above, was placed thereon. Then, the curable resin included in the electrically insulating adhesive layer was cured by UV curing. Then, the electrically insulating adhesive layer was peeled from the mold. Thus, the anisotropic conductive films of the Examples and Comparative Examples were manufactured.

### (2) Center Distance of Closest Electrically Conductive Particles

In each anisotropic conductive film of the Examples and the Comparative Examples, the center distance L1 between the reference electrically conductive particle P0 and the first electrically conductive particle P1 closest to this reference electrically conductive particle P0 is confirmed by measurement using an optical microscope. In this situation, fifty sets of 100 electrically conductive particles on the first row axis A1 connecting a center of the reference electrically conductive particle P0 and a center of the first electrically conductive particle P1 are arbitrarily measured and an average value thereof is sought to confirm the expected center distance L1. Results are shown in Table 1.

### (3) Overlap Widths W1, W2 of Adjacent Electrically Conductive Particles

In each anisotropic conductive film of the Examples and the Comparative Examples, the overlap width W1 of the electrically conductive particles P adjacent in the longitudinal direction F1 of the anisotropic conductive film and the overlap width W2 of the electrically conductive particles P adjacent in the short-side direction F2 of the anisotropic conductive film are measured using a metallurgical microscope. Results are shown in Table 1.

### (4) Conductivity Evaluation

The (a) initial conduction resistance, (b) conduction reliability, and (c) short-circuiting occurrence rate of the Examples and the Comparative Examples were each evaluated as follows. Results are shown in Table 1.

### (a) Initial Conduction Resistance

The anisotropic conductive film of each of the Examples and the Comparative Examples was sandwiched between an IC for evaluating the initial conductivity and conduction reliability and a glass substrate and heat pressed (180° C., 80 MPa, 5 seconds) so as to obtain each connected object for evaluation. In this situation, the longitudinal direction of the anisotropic conductive film and the short-side direction of the connection terminal were matched. Then, the conduction resistances of these connected objects for evaluation were measured.

Here, the terminal patterns of the IC for evaluating the initial conductivity and conduction reliability and the glass substrate corresponded to each other, and sizes thereof were as described below.

### IC for Evaluating Initial Conductivity and Conduction Reliability

Outer size: 0.7×20 mm

Thickness: 0.2 mm

Bump specifications: Gold-plated, height of 12 μm, size of 15×100 μm, bump distance of 15 μm

Glass substrate

Glass material: Manufactured by Corning Inc.

Outer size: 30×50 mm

Thickness: 0.5 mm

Electrode: ITO wiring

### (b) Conduction Reliability

The conduction resistance after placing the connected objects for evaluation, fabricated in (a) using the IC for evaluating the initial conduction resistance and each anisotropic conductive film of the Examples and the Comparative Examples, in a thermostatic chamber set to a temperature of 85° C. and a humidity of 85% RH for 500 hours was measured in the same manner as (a). Note that from the perspective of practical conduction stability of a connected electronic component, the conduction resistance preferably does not exceed 5Ω.

### (c) Short-Circuiting Occurrence Rate

As an IC for evaluating a short-circuiting occurrence rate, the following IC (comb-teeth TEG (test element group) spaced at 7.5 μm) was prepared.

Outer size: 13.5×13 mm

Thickness: 0.5 mm

Bump specifications: Gold-plated, height of 15 μm, size of 25×140 μm, bump distance of 7.5 μm

Each anisotropic conductive film of the Examples and the Comparative Examples was interposed between the IC for evaluating the short-circuiting occurrence rate and a glass substrate of a pattern corresponding to this evaluation IC and heated and pressurized under connection conditions similar to (a) to obtain a connected object, and a short-circuiting occurrence rate of this connected object was sought. The short-circuiting occurrence rate was calculated as “occurrence count of short-circuiting/total count of 7.5-μm spaces.” The short-circuiting occurrence rate being 50 ppm or greater is not preferable from a standpoint of manufacturing a connection structure for actual use.

### (5) Connected Particles

In the connected object for evaluation that was the IC for evaluating the initial conduction resistance and each anisotropic conductive film of the Examples and the Comparative Examples, a number of electrically conductive particle clusters where two electrically conductive particles present without connecting to a terminal were connected or a number of electrically conductive particle clusters where three such particles were connected was measured using a metallurgical microscope in 100 adjacent connection terminals. Results are shown in Table 1.

TABLE 1

| | | Comparative | | | |
|---|---|---|---|---|---|
| | | Example 1 | Example 1 | Example 2 | Example 3 |
| Disposition of Electrically Conductive | | FIG. 5 | FIG. 1 | FIG. 2 | FIG. 3 |
| Particles | | | | | |
| Center distance L1 (μm) of closest | | 1.6 | 2.3 | 2 | 2 |
| electrically conductive particles | | | | | |
| Overlap width | Longitudinal | 4 | 2 | 2 | 4 |
| between adjacent | direction W1 (μm) | | | | |
| electrically | Short-side direction | 4 | 2 | 4 | 2 |
| conductive particles | W2 (μm) | | | | |

| | | | | |
|---|---|---|---|---|
| Initial electrical conduction resistance | 0.2 | 0.2 | 0.2 | 0.2 |
| (Ω) | | | | |
| Conduction reliability (85° C./85% RH, | 4 | 4 | 4 | 4 |
| 500 hr) (Ω) | | | | |
| Short-circuiting occurrence rate (ppm) | 250 | <50 | <50 | <50 |
| Number of particle clusters of two | 6 | 3 | 2 | 3 |
| connected electrically conductive | | | | |
| particles (among 100 between connected | | | | |
| terminals) | | | | |
| Number of particle clusters of three | 3 | 1 | 0 | 1 |
| connected electrically conductive | | | | |
| particles (among 100 between connected | | | | |
| terminals) | | | | |

It is understood from table 1 that both the anisotropic conductive films of Examples 1 to 3 and the anisotropic conductive film of Comparative Example 1 had a high density of electrically conductive particles but also that in the anisotropic conductive film of Comparative Example 1, electrically conductive particles clusters of three connected electrically conductive particles arise such that short-circuiting was likely to occur whereas in the anisotropic conductive films of Examples 1 to 3 electrically conductive particle clusters were less likely to arise such that the terminals were less likely to short-circuit.

Furthermore, in observing these connection states, in Comparative Example 1, it was difficult to see a change before and after connection in a row state of the electrically conductive particles perhaps due to the row of the electrically conductive particles consisting of a row orthogonal to a row parallel to the bump row. However, in Examples 1 to 3, where adjacent electrically conductive particles overlap in at least the longitudinal direction or the short-side direction of the anisotropic conductive film and the overlap widths W1, W2 were less than 1 time the particle diameter of the electrically conductive particle, it was easy to grasp a change in the positions of the electrically conductive particles before and after connection.

### REFERENCE SIGNS LIST

1A, 1B, 1C, 1D Anisotropic conductive film
3 Terminal or connection terminal
10 Electrically insulating adhesive layer
A1 First row axis
A2 Second row axis
F1 Longitudinal direction of anisotropic conductive film
F2 Short-side direction of anisotropic conductive film
L1 Center distance between reference electrically conductive particle and first electrically conductive particle
L2 Center distance between reference electrically conductive particle and second electrically conductive particle
P Electrically conductive particle
P0 Reference electrically conductive particle
P1 First electrically conductive particle
P2 Second electrically conductive particle
q1 Projection image in longitudinal direction of anisotropic conductive film of reference electrically conductive particle
q2 Projection image in short-side direction of anisotropic conductive film of reference electrically conductive particle
W1 Overlap width between electrically conductive particles adjacent in longitudinal direction of anisotropic conductive film
W2 Overlap width between electrically conductive particles adjacent in short-side direction of anisotropic conductive film

9. An anisotropic conductive film, comprising: an electrically insulating adhesive layer; and electrically conductive particles disposed in a lattice form in the electrically insulating adhesive layer; wherein the electrically insulating adhesive layer contains an insulating filler, and a discretionary electrically conductive particle is defined as a reference (“reference electrically conductive particle” hereinbelow), an electrically conductive particle closest to the reference electrically conductive particle is defined as a first electrically conductive particle, and an electrically conductive particle equally close or next closest to the reference electrically conductive particle with regard to the first electrically conductive particle is defined as a second electrically conductive particle, the second electrically conductive particle being absent from a lattice form axis including the reference electrically conductive particle and the first electrically conductive particle, a projection image in a longitudinal direction of the anisotropic conductive film of the reference electrically conductive particle and the first electrically conductive particle or the second electrically conductive particle overlap, a projection image in a short-side direction of the anisotropic conductive film of the reference electrically conductive particle and the second electrically conductive particle or the first electrically conductive particle overlap, and at least a maximum width in the short-side direction of the anisotropic conductive film of an overlap region between the projection image in the longitudinal direction of the anisotropic conductive film of the reference electrically conductive particle and the first electrically conductive particle or the second electrically conductive particle (“overlap width between electrically conductive particles adjacent in the longitudinal direction of the anisotropic conductive film” hereinbelow) or a maximum width in the longitudinal direction of the anisotropic conductive film of an overlap region between the projection image in the short-side direction of the anisotropic conductive film of the reference electrically conductive particle and the second electrically conductive particle or the first electrically conductive particle (“overlap width between electrically conductive particles adjacent in the short-side direction of the anisotropic conductive film” hereinbelow) is less than 1 time a particle diameter of the electrically conductive particle.

10. The anisotropic conductive film according to claim 9, wherein the lattice form disposition of the electrically conductive particles is an oblique lattice form.

11. The anisotropic conductive film according to claim 9, wherein the overlap width between the electrically conductive particles adjacent in the longitudinal direction of the anisotropic conductive film is equal to the particle diameter of the electrically conductive particle.

12. The anisotropic conductive film according to claim 9, wherein the overlap width between the electrically conductive particles adjacent in the short-side direction of the anisotropic conductive film is equal to the particle diameter of the electrically conductive particle.

13. The anisotropic conductive film according to claim 9, wherein at least the overlap width between the electrically conductive particles adjacent in the longitudinal direction of the anisotropic conductive film or the overlap width between the electrically conductive particles adjacent in the short-side direction of the anisotropic conductive film is less than 0.5 times the particle diameter of the electrically conductive particle.

14. The anisotropic conductive film according to claim 9, wherein a center distance between the reference electrically conductive particle and the first electrically conductive particle and a center distance between the reference electrically conductive particle and the second electrically conductive particle are from 1.5 to 2000 times the particle diameter of the electrically conductive particle.

15. The anisotropic conductive film according to claim 9, wherein the center distance between the reference electrically conductive particle and the first electrically conductive particle and the center distance between the reference electrically conductive particle and the second electrically conductive particle are from 1.5 to 5 times the particle diameter of the electrically conductive particle.

16. A connection structure, comprising:
a first electronic component, and a second electronic component, wherein the first component and the second electronic component are anisotropically conductively connected via the anisotropic conductive film according to claim 9.

17. The connection structure according to claim 16, wherein there is less than six electrically conductive particle clusters where two electrically conductive particles are connected among 100 electrically conductive particles present between connection terminals.

18. The connection structure according to claim 16, wherein there is less than three electrically conductive particle clusters where three electrically conductive particles are connected among 100 electrically conductive particles present between connected terminals.

19. A design method of an anisotropic conductive film where the anisotropic conductive film, which includes an electrically insulating adhesive layer and electrically conductive particles disposed in a lattice form in the electrically insulating adhesive layer, is used to make an anisotropic conductive connection between a terminal of a first electronic component and a terminal of a second electronic component, wherein a discretionary electrically conductive particle is defined as a reference (“reference electrically conductive particle” hereinbelow), an electrically conductive particle closest to the reference electrically conductive particle is defined as a first electrically conductive particle, and an electrically conductive particle equally close or next closest to the reference electrically conductive particle with regard to the first electrically conductive particle is defined as a second electrically conductive particle, the second electrically conductive particle being absent from a lattice form axis including the reference electrically conductive particle and the first electrically conductive particle, a projection image in a longitudinal direction of the anisotropic conductive film of the reference electrically conductive particle and the first electrically conductive particle or the second electrically conductive particle overlap, a projection image in a short-side direction of the anisotropic conductive film of the reference electrically conductive particle and the second electrically conductive particle or the first electrically conductive particle overlap, and at least a maximum width in the short-side direction of the anisotropic conductive film of an overlap region between the projection image in the longitudinal direction of the anisotropic conductive film of the reference electrically conductive particle and the first electrically conductive particle or the second electrically conductive particle (“overlap width between electrically conductive particles adjacent in the longitudinal direction of the anisotropic conductive film” hereinbelow) or a maximum width in the longitudinal direction of the anisotropic conductive film of an overlap region between the projection image in the short-side direction of the anisotropic conductive film of the reference electrically conductive particle and the second electrically conductive particle or the first electrically conductive particle (“overlap width between electrically conductive particles adjacent in the short-side direction of the anisotropic conductive film” hereinbelow) is less than 1 time a particle diameter of the electrically conductive particle, wherein the first electronic component is selected from a flexible board, a glass board, a plastic board, or a ceramic board and the second electronic component is selected from an IC chip, an IC module, or a flexible board and the disposition of the electrically conductive particles is set so that the connection between the electrically conductive particles between the terminals after connection is three particles or fewer.

20. A design method of an anisotropic conductive film including an electrically insulating adhesive layer and electrically conductive particles disposed in a lattice form in the electrically insulating adhesive layer, wherein a discretionary electrically conductive particle is defined as a reference (“reference electrically conductive particle” hereinbelow),
an electrically conductive particle closest to the reference electrically conductive particle is defined as a first electrically conductive particle, and an electrically conductive particle equally close or next closest to the reference electrically conductive particle with regard to the first electrically conductive particle is defined as a second electrically conductive particle, the second electrically conductive particle being absent from a lattice form axis including the reference electrically conductive particle and the first electrically conductive particle, a projection image in a longitudinal direction of the anisotropic conductive film of the reference electrically conductive particle and the first electrically conductive particle or the second electrically conductive particle overlap, a projection image in a short-side direction of the anisotropic conductive film of the reference electrically conductive particle and the second electrically conductive particle or the first electrically conductive particle overlap, and at least a maximum width in the short-side direction of the anisotropic conductive film of an overlap region between the projection image in the longitudinal direction of the anisotropic conductive film of the reference electrically conductive particle and the first electrically conductive particle or the second electrically conductive particle (“overlap width between electrically conductive particles adjacent in the longitudinal direction of the anisotropic conductive film” hereinbelow) or a maximum width in the longitudinal direction of the anisotropic conductive film of an overlap region between the projection image in the short-side direction of the anisotropic conductive film of the reference electrically conductive particle and the second electrically conductive particle or the first electrically conductive particle (“overlap width between electrically conductive particles adjacent in the short-side direction of the anisotropic conductive film” hereinbelow) is less than 1 time a particle diameter of the electrically conductive particle, wherein the disposition of the electrically conductive particles is set so that when an anisotropic conductive connection is made to a connected body having a connection terminal where a width of the connection terminal is less than 7 times an electrically conductive particle diameter D and a minimum inter-terminal distance is less than 4 times the electrically conductive particle diameter D, the connection between the electrically conductive particles between the terminals after connection is three particles or fewer.

21. The design method according to claim 19, wherein the particle diameter is from 1 to 30 μm and an electrically conductive particle center distance is from 1.5 to 2000 times the particle diameter.

22. The design method according to claim 19, wherein a count density of the electrically conductive particles is from 400 to 250000 particles/mm².

23. The design method according to claim 19, wherein the lattice form disposition is an oblique lattice form.

24. The design method according to claim 19, wherein the electrically insulating adhesive layer contains an insulating filler.
